(19) United States
(12) Patent Application Publication
(10) Pub. No.: US 2023/0055809 A1
(43) Pub. Date: Feb. 23, 2023

(54) DIGITAL MICROMIRROR DEVICE WITH REDUCED STICTION

(71) Applicant: Texas Instruments Incorporated, Dallas, TX (US)

(72) Inventors: Jacky Dale Grimmett, Prosper, TX (US); Ryan Patrick Savage, Richardson, TX (US)

(21) Appl. No.: 17/888,636

(22) Filed: Aug. 16, 2022

Related U.S. Application Data
(60) Provisional application No. 63/234,329, filed on Aug. 18, 2021.

(51) Int. Cl. G02B 26/08; G02B 7/182; B81B 3/00

(52) U.S. Cl. CPC G02B 26/0841; G02B 7/1821; B81B 3/001; B81B 2201/042

(57) ABSTRACT

An example includes: an electrode layer including address electrodes and a hinge base; a hinge layer over the electrode layer, the hinge layer including: a torsional hinge having a longitudinal axis between opposite ends; a first single spring tip and a second single spring tip spaced from the torsional hinge; and raised electrodes spaced from the torsional hinge, from the first single spring tip, and from the second single spring tip; and a mirror over the hinge layer, the mirror having a tilt axis on a diagonal between a first corner and a second corner, the tilt axis aligned with the longitudinal axis of the torsional hinge, the mirror having a first tilting corner and a second tilting corner opposing one another across the tilt axis, the first single spring tip under the first tilting corner and the second single spring tip under the second tilting corner.

### CROSS-REFERENCE TO RELATED APPLICATIONS

This application claims the benefit of and priority to U.S. Provisional Application No. 63/234,329, filed Aug. 18, 2021, which Application is hereby incorporated herein by reference in its entirety.

### TECHNICAL FIELD

This relates generally to digital micromirror devices.

### BACKGROUND

Digital micromirror devices (DMDs) are microelectromechanical systems (MEMS) devices that can be used as reflective spatial light modulators. Example DMDs can use amplitude or phase modulation to project light or to project images. Projectors, displays, head up displays, virtual reality and augmented reality vision systems, printers, 3D printers, spectrometers, ranging devices, machine vision, cameras, light sensors and light sources such as automotive headlights or other vehicle headlamps are example applications that can use DMDs. Optical networking systems and light switches can be implemented using DMDs. Visible light including monochrome or colored light can be used with DMDs, and other light including infrared and ultraviolet light can be used with DMDs.

### SUMMARY

An example includes: an electrode layer including address electrodes and a hinge base; a hinge layer over the electrode layer, the hinge layer including: a torsional hinge having a longitudinal axis between opposite ends; a first single spring tip and a second single spring tip spaced from the torsional hinge; and raised electrodes spaced from the torsional hinge, from the first single spring tip, and from the second single spring tip; and a mirror over the hinge layer, the mirror having a tilt axis on a diagonal between a first corner and a second corner, the tilt axis aligned with the longitudinal axis of the torsional hinge, the mirror having a first tilting corner and a second tilting corner opposing one another across the tilt axis, the first single spring tip under the first tilting corner and the second single spring tip under the second tilting corner.

An additional example includes: an electrode layer including address electrodes; a mirror layer including a mirror configured to tilt about a tilt axis that runs diagonally between a first corner and a second corner, the mirror having a first tilting corner and a second tilting corner; and a hinge layer over the address electrodes and beneath the mirror layer, the hinge layer including: a torsional hinge having a longitudinal axis between two ends; raised electrodes spaced from the torsional hinge; and a first spring tip beneath the first tilting corner and a second spring tip beneath the second tilting corner, the first tilting corner configured to contact the first spring tip when the mirror tilts at a first angle with respect to a horizontal position, and the second tilting corner configured to contact the second spring tip when the mirror tilts at a second angle with respect to the horizontal position.

A further example includes: a semiconductor substrate; and an electrode layer over the semiconductor substrate, the electrode layer including a first address electrode, a second address electrode spaced apart from the first address electrode, and a hinge base spaced from the first address electrode and the second address electrode. A hinge layer is over the electrode layer, the hinge layer including: a torsional hinge having a longitudinal axis between opposite ends; a first single spring tip and a second single spring tip spaced from the torsional hinge; and raised electrodes spaced from the torsional hinge, from the first single spring tip, and from the second single spring tip. A mirror is over the hinge layer, the mirror having a tilt axis on a diagonal between a first corner and a second corner, the tilt axis aligned with the longitudinal axis of the torsional hinge. A first spring tip via is supporting the first single spring tip and a second spring tip via is supporting the second single spring tip, the first spring tip via and the second spring tip via mechanically and electrically coupling the first spring tip and the second spring tip, respectively, to the hinge base; and the first single spring tip under the first tilting corner and the second single spring tip under the second tilting corner.

### BRIEF DESCRIPTION OF THE DRAWINGS

For a more complete understanding of the illustrative examples of aspects of the present application that are described herein and the advantages thereof, reference is now made to the following descriptions taken in conjunction with the accompanying drawings, in which:

FIG. 1 illustrates in a block diagram a system for projection using a digital micromirror device (DMD).

FIG. 2 illustrates the operation of a mirror.

FIG. 3A illustrates in a plan view a portion of a DMD with mirrors in an on state and in an off state; and FIG. 3B illustrates in a cross sectional view the tilt operations of mirrors in an on state and in an off state.

FIG. 4 illustrates, in a plan view, a portion of a DMD with mirrors in an orthogonal arrangement.

FIG. 5A illustrates, in a partially exploded view, the metal layers and vias used to form a pixel of an example arrangement, FIG. 5B illustrates, in a projection view, the pixel of FIG. 6A with a mirror in a landed tilt position, and FIG. 5C illustrates in another projection view the pixel of FIGS. 5A-5B viewed along a tilt axis.

FIGS. 6A-6D illustrate, in plan views, the metal layers and vias used to implement the example pixel shown in FIGS. 5A-5C. FIGS. 6E-6F are cross sections taken along the tilt and roll axis of the mirror of FIG. 6D. FIG. 6G illustrates in a partial cutaway projection a pixel incorporating features of an arrangement.

FIG. 7 illustrates in a plan view an example orientations of a pixel of the arrangements oriented for use in an orthogonal DMD array.

FIG. 8A illustrates, in a close up projection view, additional details of a spring tip used with the arrangements. FIG. 8B illustrates, in a top view, a comparison of two alternative spring tips for use with the arrangements.

FIG. 9 illustrates, in a block diagram, a system for use in an arrangement.

Corresponding numerals and symbols in the different figures generally refer to corresponding parts unless otherwise indicated. The figures are drawn to clearly illustrate the relevant aspects of the illustrative example arrangements and are not necessarily drawn to scale.

### DETAILED DESCRIPTION

The making and using of example arrangements that incorporate aspects of the present application are discussed in detail below. It should be appreciated, however, that the examples disclosed provide many applicable inventive concepts that can be embodied in a wide variety of specific contexts. The specific examples and arrangements discussed are illustrative of specific ways to make and use the various arrangements, and the examples described do not limit either the scope of the specification, or the scope of the appended claims.

For example, when the term “coupled” is used herein to describe the relationships between elements, the term as used in the specification and the appended claims is to be interpreted broadly, and is not limited to connected or directly connected but instead the term “coupled” may include connections made with intervening elements, and additional elements and various connections may be used between any elements that are coupled. The term “optically coupled” is used herein. Elements that are “optically coupled” have an optical connection between the elements but various intervening elements can be between elements that are optically coupled.

The term “pixel” is used herein. Pixel is an abbreviation of the term “picture element.” A pixel is the smallest addressable element used in a digital display. A DMD pixel is one element of an array of addressable picture elements that display a pattern on the DMD for modulating light. DMDs can be used to implement a spatial light modulator (“SLM”). In a DMD, the pixels are mirrors. In an example, the SLM is a digital micromirror device and the pixels are formed by mirrors which are a few microns wide and are often referred to as micromirrors. The SLM can have thousands or millions of pixels arranged in rows and columns. In amplitude modulating SLMs implemented using DMDs, when the DMDs are illuminated, the pixels can be described as being in an “on state” or in an “off state”. In the arrangements, a pixel in an on state modulates the illumination light to produce on state light that is arranged to be projected as an image. A pixel in an off state modulates light to produce off state light that is directed away from the projection elements. In this manner the SLM produces projected images.

A DMD contains moveable mirrors that can be rapidly positioned according to stored data. In an example DMD device, an array of picture elements (“pixels”), where each pixel is a mirror, are arranged in a two dimensional array. Each mirror has a corresponding memory element, such as a complementary metal oxide semiconductor (CMOS) static random access memory (SRAM) cell. Data corresponding to an image is loaded into the memory cells, and when the mirrors are powered and switched according to the stored data in the memory cells, the mirrors can tilt to one of two positions, with a first position corresponding to an on state, reflecting illumination light to be projected by the system, or to a second position corresponding to an off state, reflecting light away from the projector in the system. A system including the DMD can rapidly switch patterns so that a wide range of intensity and colors can be displayed by loading the DMD array with a variety of patterns, and illuminating the device many times in a frame period. Intensity gradients can be accomplished using pulse width modulation to switch and illuminate the DMD pattern. High resolution and high contrast can be achieved for systems implemented using DMDs.

The mirrors are subject to stiction, friction that tends to prevent the surface of a mirror from moving from a landing point. Stiction tends to keep the mirror in a tilted position. If stiction force exceeds the return forces on the mirror, in some situations stuck mirrors can result. When the mirrors are used as spatial light modulators, a stuck mirror can cause visible defects in the projected images. Reductions in mirror dimensions, such as when a manufactured mirror device is reduced in size from a prior size by dimensional scaling, can increase stiction.

In this description, a DMD mirror is described as having a “tilt axis” and a “roll axis”. A mirror in the arrangements is mounted to a torsional hinge that can rotate along a longitudinal axis, and a diagonal of the mirror is mounted to the hinge and spaced above it, and diagonal of the mirror, the tilt axis, is aligned with the longitudinal axis of the torsional hinge. When electrostatic force is applied to the mirror, the electrostatic force causes the mirror to tilt along the tilt axis. The roll axis is perpendicular to the tilt axis and intersects the tilt axis at the center of the mirror. In operation, two opposing corners of the mirror perpendicular to the tilt axis can move by tilting the mirror in one of two directions, rotating the torsional hinge along the longitudinal axis. A landing tip of a spring tip that provides at least one landing point for the tilted mirror is placed along the roll axis, in one example the landing tip of the spring tip is placed exactly aligned with the roll axis. The spring tip is flexible and provides a landing point for the bottom surface of the mirror.

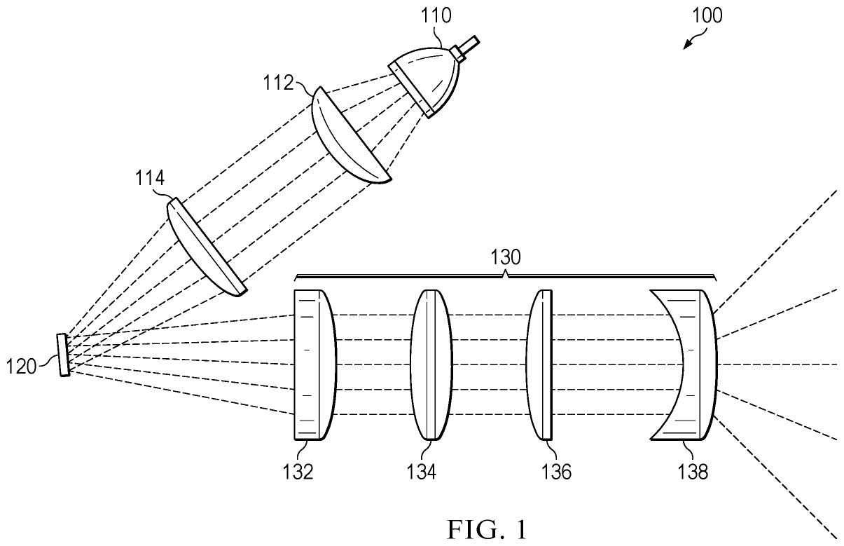

FIG. 1 is a block diagram illustrating an example arrangement for a projection system 100. In FIG. 1, a light source 110 produces light, which is transmitted through collection and collimating lens 112. The light beam from the collimating lens 112 travels to a beam shaping lens 114, where the light is focused on the surface of a DMD 120. The light beam is then reflected from mirrors of the DMD 120 to the projection lens set 130, which in this example includes a doublet lens 132, a focusing lens 134, a cylindrical lens 136 and an anamorphic lens 138. The arrangements are useful with many applications where DMDs are used, for example digital image projectors including portable projectors, pico-projectors used in smart phones and tablets, video displays, heads up displays, cinema and presentation projectors, video games, LIDAR systems, window displays, smart headlights, and near eye displays, such as virtual reality or augmented reality headsets, glasses, and displays. When color projectors are used, the number of light sources may be increased, for example red, green and blue light emitting diodes (LEDs) can be used to illuminate the SLM in sequential red-green-blue operations to project color images. Alternative arrangements include using phosphor wheels, color filters, color laser diodes, and/or static phosphors to produce multiple colors.

The light source 110 can produce white light using LEDs, other white light sources are also useful. Alternatives include using a blue laser to excite a yellow phosphor, a halogen light, or an incandescent light.

After the illuminating light beam is received by the DMD 120, according to image information supplied electronically from an image projection circuit or system, a pattern displayed on the DMD 120 modulates the light. The modulated light is reflected from the DMD 120 and enters the projection lens set 130. Anamorphic lens 138 may also reshape the light beam to meet a desired aspect ratio. In other applications, the anamorphic lens elements may be omitted, and uniform illumination of the DMD 120 and a uniform light distribution in the projected image may be used.

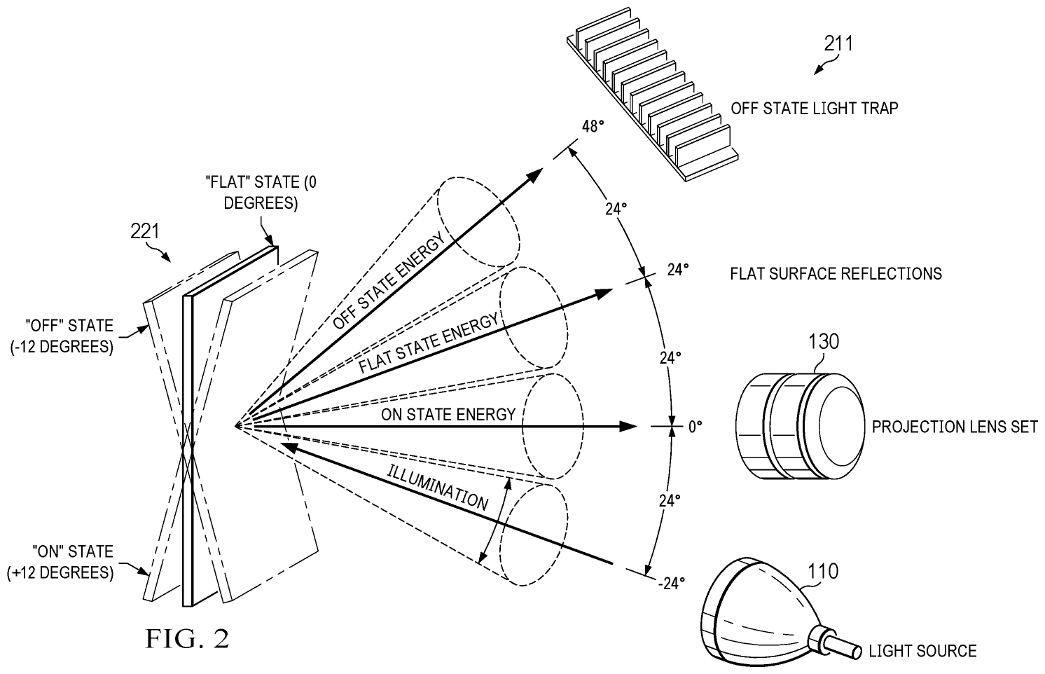

FIG. 2 illustrates the operation of an example mirror 221. A DMD used in the arrangements will have thousands, hundreds of thousands, or even millions of mirrors in a two dimensional array. The example mirror 221 tilts at +/−12 degrees. In DMD devices, varying mirror tilt angles are used such as +/−10 degrees, +/−14 degrees, or +/−17 degrees. When the mirror 221 is not powered, the mirror has a flat state position, which is designated ““FLAT” STATE (0 DEGREES)” in FIG. 2. When the mirror 221 is in an “OFF” STATE, it tilts away from the flat position to a−12 degree position, and the illumination light received from the light source 110 is reflected to be directed away from the projection lens set 130 and towards a light trap designated OFF STATE LIGHT TRAP 211. When the mirror 221 is in an “ON” STATE, the mirror 221 tilts to a+12 degree position and the illumination light from light source 110 is reflected from the mirror to the projection lens set 130 designated PROJECTION LENS SET. In the FLAT state, the reflected light would be directed to the ray labeled FLAT SURFACE REFLECTIONS, however in a system no illumination is presented to mirrors in the FLAT state so little light would be reflected as FLAT SURFACE REFLECTIONS. As is further described below, in a DMD of the arrangements, an array of memory cells in rows and columns is coupled to the array of mirrors, and the memory cells are written with display data. When the mirrors are updated, the entire array of mirrors changes position in correspondence with the pattern stored in the memory array, the mirrors taking positions determined by the data stored in the associated memory cell. In an arrangement for a device, the memory cells are formed in a silicon substrate in rows and columns, and the mirrors form a mirror array, having rows and columns, over the array of memory cells. The mirrors lie over corresponding memory cells that store data that control the motion of the individual mirrors.

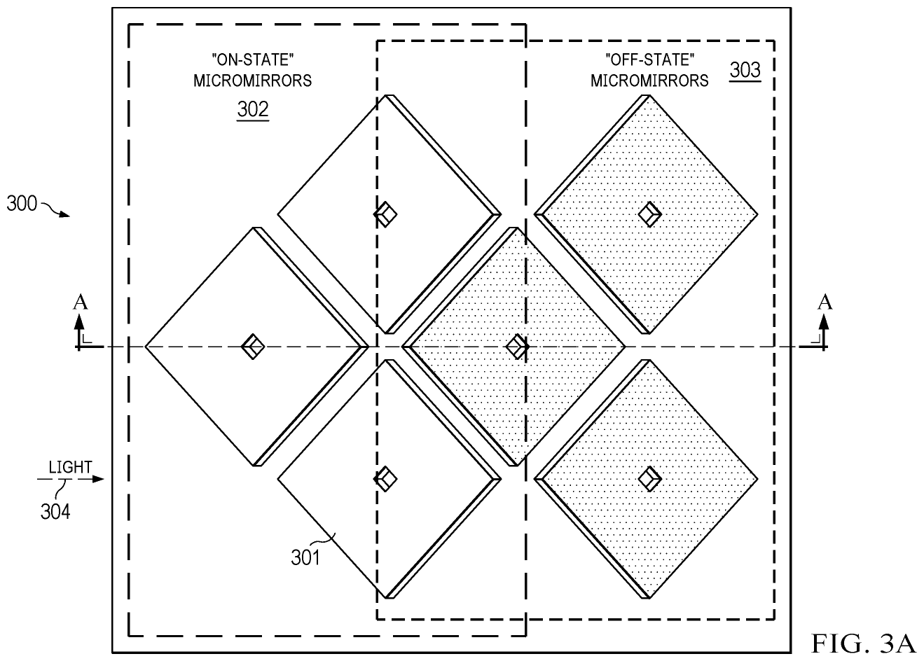

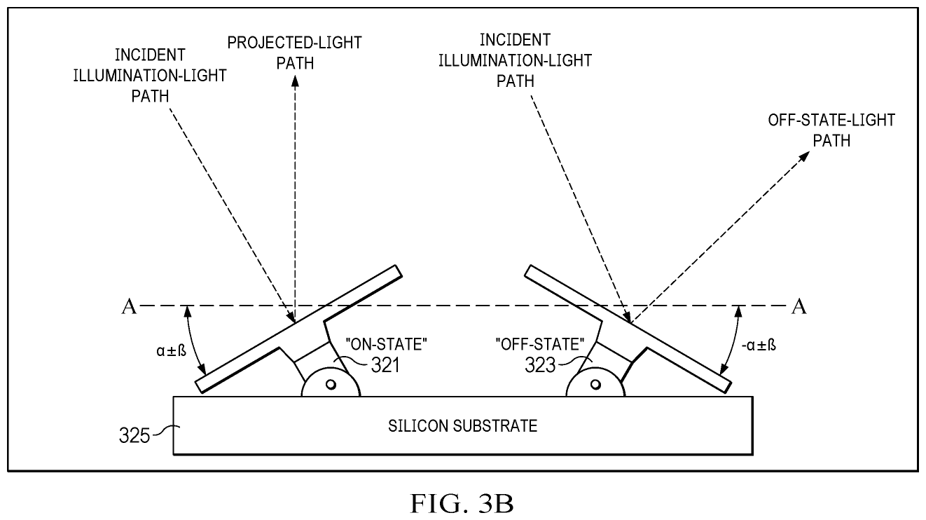

FIGS. 3A and 3B illustrate the operation of a portion 300 of the mirrors 301 in a diamond oriented DMD micromirror array. In FIG. 3A, mirrors 302 are labeled “ON-STATE” MICROMIRRORS and are shown as bright, indicating the light is being projected towards the viewer. Mirrors 303 are labeled “OFF-STATE” MICROMIRRORS″ and are shaded dark, indicating the light is being reflected away from the viewer, and into a light trap (not shown in FIG. 3A). Illumination light 304 labeled “LIGHT” enters the array of mirrors 301 from the left side (as oriented in FIG. 3A).

FIG. 3B shows the operation of an “ON-STATE” mirror and an “OFF-STATE” mirror in a cross sectional view taken along line A-A in FIG. 3A. The mirrors 321 and 323 are shown over a silicon substrate 325. Mirror 321 is in the “ON-STATE”, and is tilted to a positive angle+α with a tolerance+/−β. In the example shown in FIG. 3B, a can be 10 degrees, 12 degrees, 14 degrees, 17 degrees or another angle. The incident illumination light is reflected by the “ON-STATE” mirror 321 towards a path designated the “PROJECTED-LIGHT PATH”. Mirror 323 is in the “OFF-STATE”, and is shown tilted to an angle−α+/−β. The illumination light (designated “INCIDENT ILLUMINATION LIGHT PATH”) is then reflected away from the projection light path to the “OFF-STATE-LIGHT PATH”, and to a light trap (not shown). Using DMDs to modulate the intensity of the incident light is a subtractive process; if all of the mirrors in an array are in the ON state for a given display time, all of the incident illumination light is reflected to a projection light path. For any mirrors in the OFF state, the incident illumination light is reflected away from the projection light path. By loading bit map patterns onto the DMD, the intensity of the light is modulated, and images can be projected. Pulse width modulation of the patterns displayed on the DMD can be used to further vary intensity and to vary color intensity when color illumination is used.

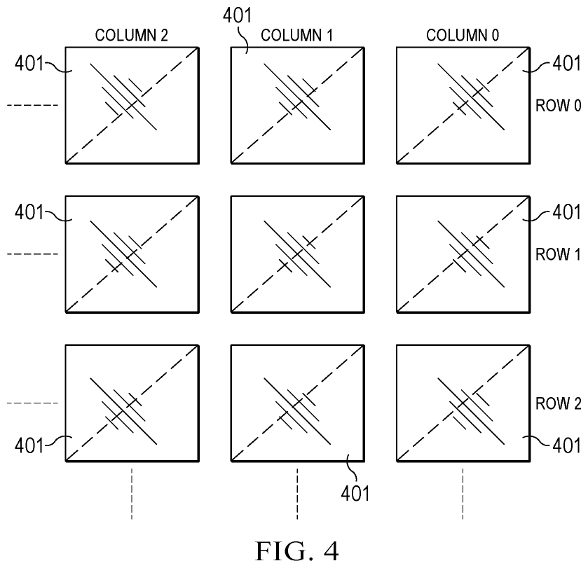

FIG. 4 illustrates, in a plan view, a portion of an array of mirrors 401 in an orthogonal arrangement. In FIG. 4, the mirrors 401 tilt about a diagonal mirror tilt axis, and the sides of the mirrors are spaced apart but parallel to one another, with rows and columns of the mirrors aligned. In contrast, in the DMD mirror array shown in FIG. 3A with a diamond pixel orientation, the rows and columns are staggered and the pixels in adjacent rows are interlaced to provide the needed coverage.

As DMD technology advances, and for semiconductor devices and MEMS devices generally, devices are increasingly made smaller in size. When fabrication processes advance to support smaller mirrors and circuitry, dimensional scaling may be used to shrink device sizes. Smaller mirror sizes and smaller DMD sizes allow for smaller systems and increased yields on semiconductor wafers as more devices are made on a wafer, reducing costs. Smaller mirrors can also be used to increase resolution by using more pixels per device and by using more pixels per unit area.

When DMD mirrors are reduced in size by dimensional scaling, it has been determined in experiments and by analysis that the forces on the mirror due to stiction, and the opposing electrostatic forces that work to return the mirror to a flat position, do not scale linearly. At some pixel pitch dimensions, a conventional mirror has a cross over point at a pixel size where stiction forces exceed the electrostatic forces, and stuck mirrors can be expected. As stuck mirrors are a defect in an SLM, this effect (increasing relative stiction with reduced mirror scaling) restricts the possibility of reducing pixel size. A conventional mirror design has two spring tips beneath each tilting corner of the mirror, and when tilted, the mirror contacts two spring tip landing tips. In the arrangements, a single spring tip is used for the tilting corners of the mirror, and the tilted mirror contacts a single spring tip landing tip, which can reduce stiction by up to 50%. Use of the arrangements enables additional reduction in mirror dimensions without increasing the stuck mirror problems which can result when shrinking mirrors formed using conventional approaches.

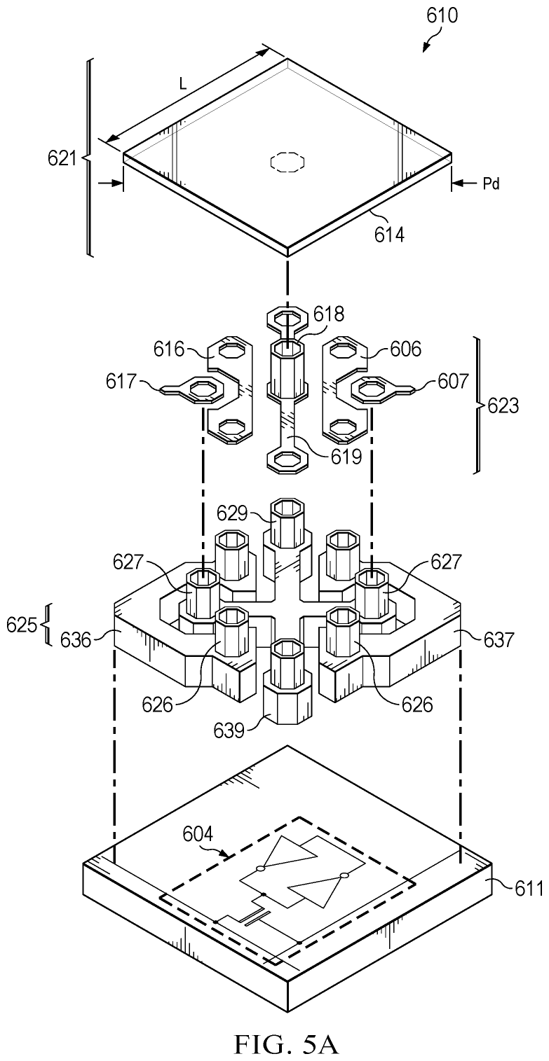

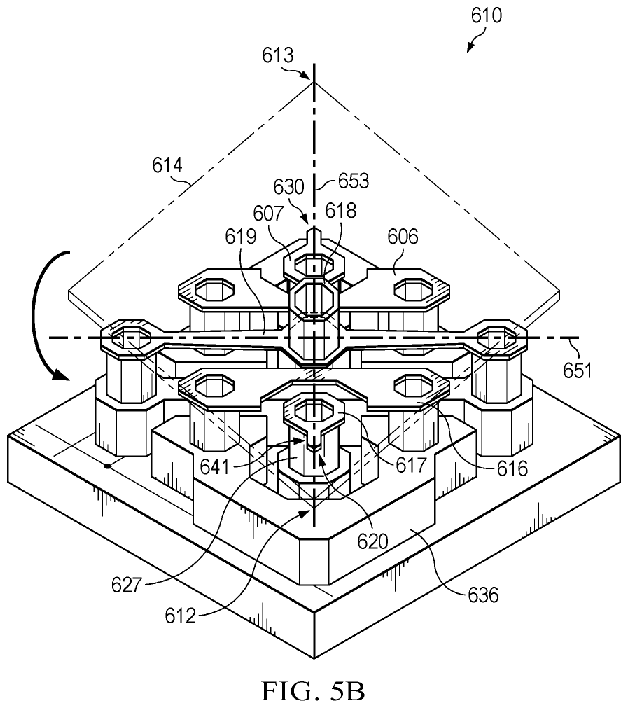

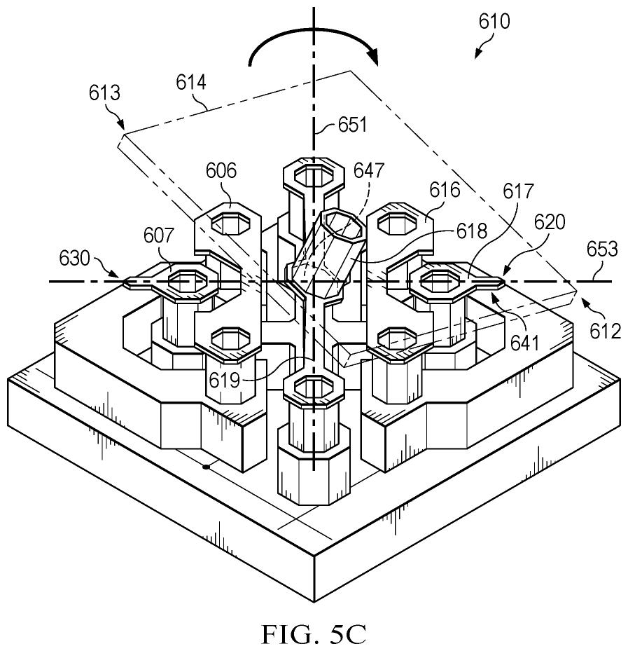

FIG. 5A illustrates in a partially exploded view a pixel 610 of an arrangement that provides reduced stiction, among other advantages. In FIG. 5A, the pixel 610 is a microelectromechanical system (MEMS) structure over a memory cell 604 in a semiconductor substrate 611. There are three layers shown in the exploded view, moving from top to bottom as oriented in FIG. 5A, a mirror layer 621, a hinge layer 623, and an electrode layer 625. In an example process used to form an arrangement, these layers are of aluminum or aluminum alloys. Aluminum and aluminum alloys are useful as a material for DMD pixels because aluminum can be polished and made highly reflective, which is desirable for mirrors. Other metals such as gold, nickel, palladium, silver, copper and alloys of these metals, which are used in semiconductor processes, can be used, and plating layers can be added to the metal layers. In an example, the mirror layer 621 and electrode layer 625 are of aluminum or aluminum alloys that can be the same material, but in alternative arrangements, different materials or metals can be used for different layers. In an example, the hinge layer 623 contains aluminum or an aluminum alloy, such as titanium and aluminum alloys (AlxTiy), for example Al₃Ti. The hinge layer 623 can have a thickness between 20-35 nanometers, with the thickness varying with pixel pitch, and pixels having smaller pitch will have a smaller thickness. The mirror layer 621 can be an aluminum or aluminum alloy having a thickness of between 120-220 nanometers, again the thickness depending on pixel pitch. The mirror layer 621 forms mirror 614 and can be polished to increase reflectivity.

In FIG. 5A, the pixel 610 includes mirror 614, which has a reflective surface such as a polished aluminum. The DMD mirrors are rectangular, and in the illustrated examples, the mirror 614 is square or diamond shaped with equal length sides L. In an example, the mirror 614 has a diagonal pitch Pd of 6.4 microns and a side length L of about 5.4 microns. Other examples include a diagonal pitch Pd of about 7.6 microns with a side length L of about 5.4 microns, a diagonal pitch Pd of about 10.8 microns with a side length L of about 7.6 microns, and a diagonal pitch Pd of about 12.8 microns with a side length L of about 9.0 microns. In future examples, the mirror size will be reduced further to less than 6.4 microns of diagonal pitch. As processes for fabricating the mirrors continue to advance, additional reduction in pixel dimensions are expected and desireable.

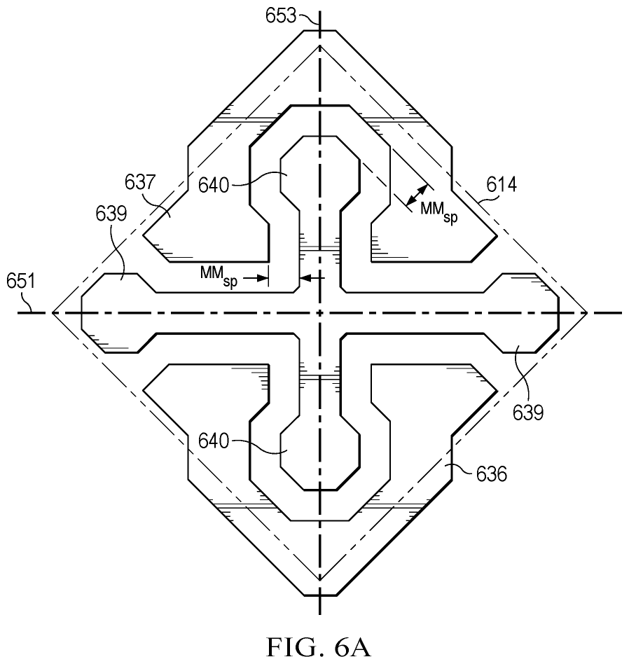

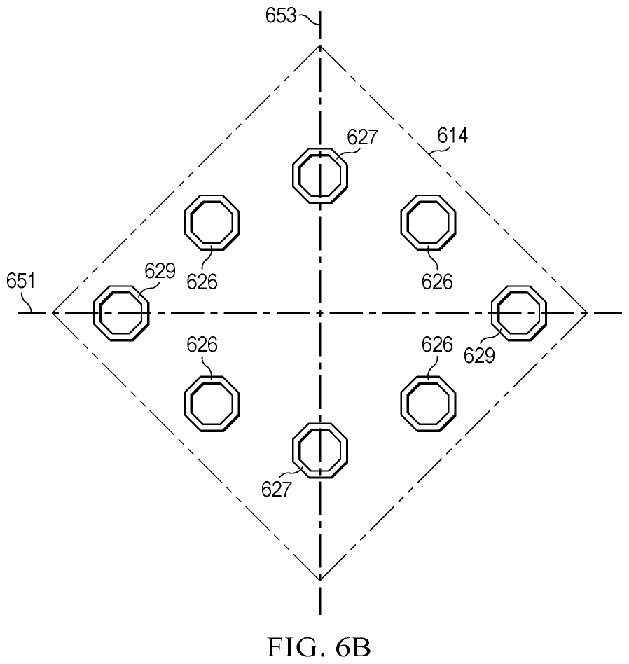

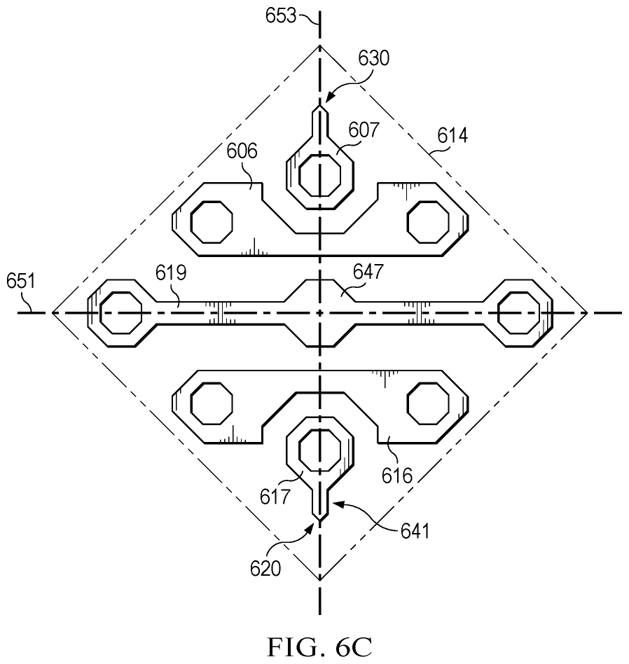

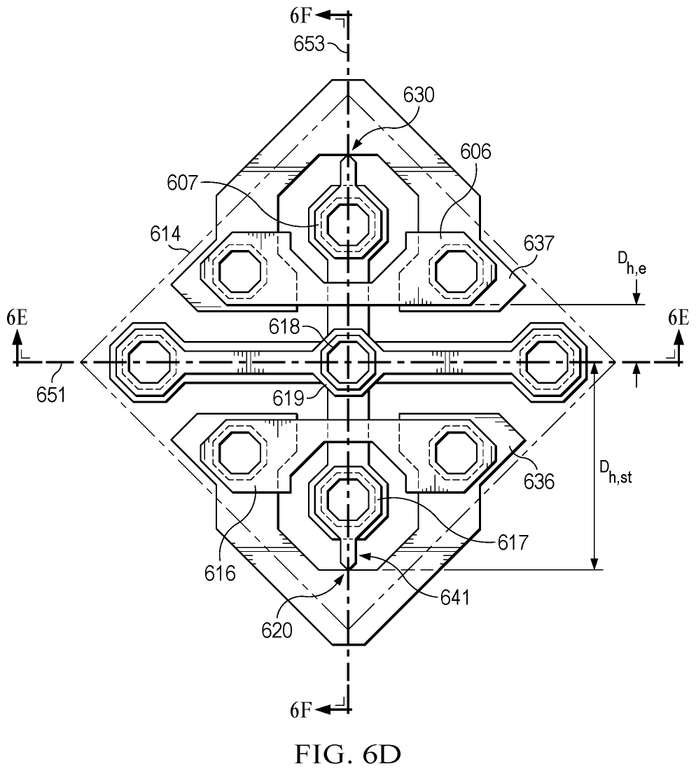

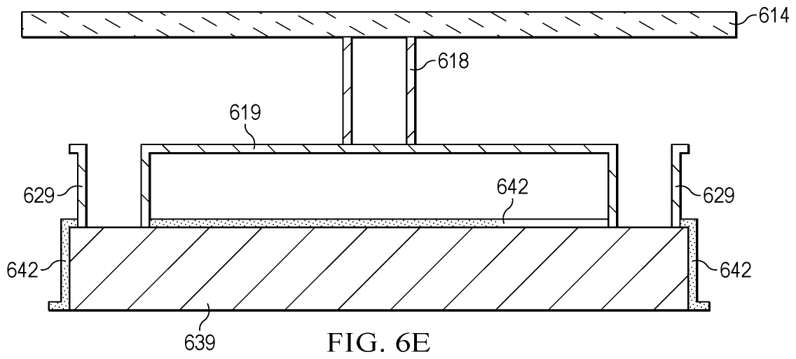

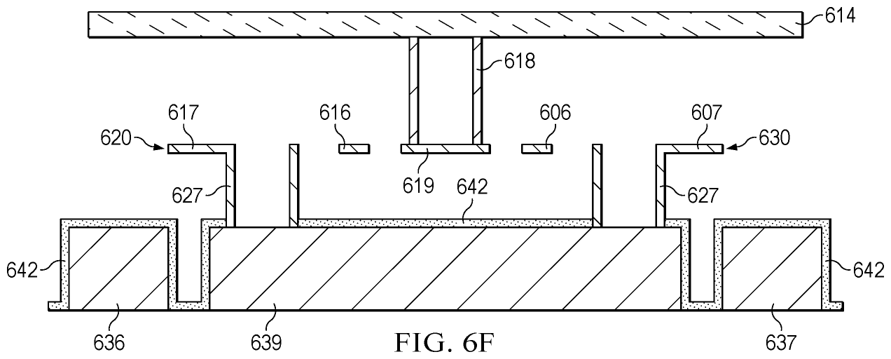

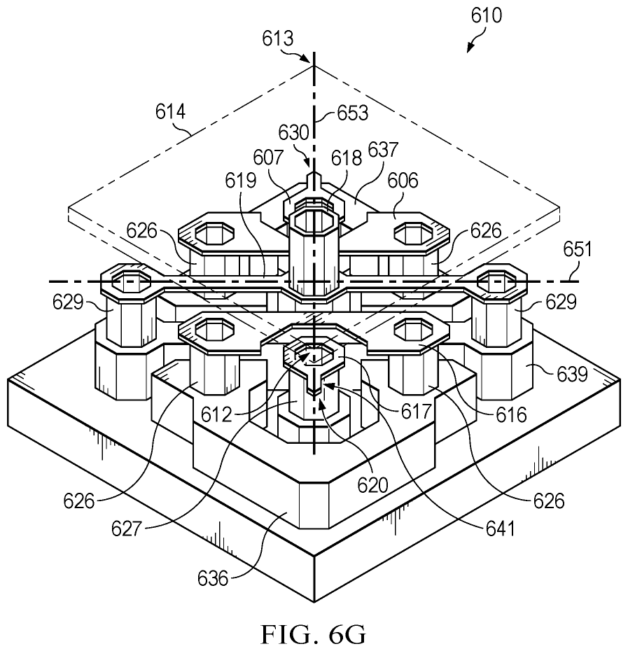

When the pixel 610 is formed, a metal deposition step and a sacrificial material deposition are used to form the electrode layer 625 and the hinge layer 623, and a metal deposition step is used to form mirror layer 621. The three layers 621, 623, 625 are formed with photolithography steps including metal deposition, photoresist deposition, pattern, and etch. The electrode layer 625 and hinge layer 623 are each deposited and patterned, and then covered with a sacrificial spacer layer (not shown, as FIG. 6A illustrates the pixel 610 after manufacture is completed, with the sacrificial spacer layers removed) such as a hardened photoresist or removable polymer. Vias are formed by patterning openings in these sacrificial layers which are then filled or plated with metal. In one approach, when the metal layers are deposited on the sacrificial layers, the deposited metal layer extends through the openings in the sacrificial layers in the via positions, and when the sacrificial layers are later removed in an etching step, the vias are formed as hollow or filled support posts or columns extending between the metal layers, which are spaced apart by air gaps. The vias form vertical mechanical supports for the hinge layer features and for the mirrors, and make electrical connections between the metal layers.

Electrode layer 625 includes two address electrodes 636 and 637, and a hinge base 639 that is spaced from the address electrodes 636 and 637. The hinge base 639 includes via pads for hinge vias 629 and additional via pads for spring tip vias 627. The address electrodes 636, 637 include via pads for raised electrode vias 626.

The electrode layer 625, the lowest metal layer in pixel 610, is the closest metal layer to the semiconductor substrate 611 and can be formed over a dielectric using a metal sputter deposition. Aluminum and aluminum alloys can be used. In an example process, the electrode layer 625 is then patterned using photolithography. A first sacrificial layer (not shown, as it is later removed prior to the completion of pixel 610) is then deposited over the electrode layer 625 and patterned to form openings corresponding to the hinge vias 629, the raised electrode vias 626, and the spring tip vias 627 in the first sacrificial layer. These openings can be filled in the subsequent metal deposition step for hinge layer 623, or in an alternative via process the openings can be filled with a via conductor material or plated with a via conductor material before the hinge layer 623 is deposited.

The hinge layer 623 includes raised electrodes 606, 616, torsional hinge 619, and spring tips 607, 617. In the arrangements, the spring tips 607, 617 in the hinge layer 623 are spaced from the torsional hinge 619 and from the raised electrodes 606, 616. The torsional hinge 619 is supported on both ends by hinge vias 629. The hinge vias 629 physically and electrically couple the torsional hinge 619 to the hinge base 639 of electrode layer 625. The torsional hinge 619 is held under tension by the hinge vias 629 to provide the torsional force that tends to return the torsional hinge 619 to a horizontal position, and to return mirror 614 to a flat position.

The mirror layer 621 includes mirror 614. Mirror 614 is spaced from the torsional hinge 619 by an air gap that is sufficiently large to allow mirror 614 to tilt above the torsional hinge. A mirror via 618 mechanically connects a central pad portion of the torsional hinge 619 to the mirror 614 at a center position of the mirror. The mirror via 618 couples a central pad on the torsional hinge 619 to the mirror 614 mechanically and electrically. In a DMD using the arrangements, a bias voltage can be applied to the mirrors of the pixels in the DMD by a power supply that can be coupled to the hinge base 639 of the pixels, providing control of a bias voltage of the mirrors. The mirrors can be tilted by electrostatic forces that are applied between the mirrors, the raised electrodes and the address electrodes.

In an example fabrication process, the hinge layer 623 is formed over a first sacrificial spacer layer (not shown) by metal deposition and is patterned using photolithographic techniques including pattern and etch processes. The hinge vias 629, the spring tip vias 627, and the raised electrode vias 626 are formed in openings formed in the first sacrificial layer before it is removed. A second sacrificial spacer layer (not shown) which can also be a hardened photoresist, is applied over the hinge layer 623 and patterned to form an opening for the mirror via 618 on a central pad of the torsional hinge 619. The mirror layer 621 is then deposited and patterned over the second sacrificial layer. The mirror via 618 will enable the mirror 614 to tilt when the torsional hinge 619 is rotated along its longitudinal axis, and the mirror 614 can tilt in one of two directions around a mirror tilt axis that parallels the longitudinal axis of the torsional hinge 619, tilting two opposite tilting corners of the mirror that lie along the roll axis, perpendicular to the torsional hinge 619.

The address electrodes 636, 637 of the electrode layer 625 are electrically coupled to the memory cell 604 that is formed in the semiconductor substrate 611. The raised electrodes 606, 616 are electrically coupled to the address electrodes 636, 637 by the raised electrode vias 626 and in operation, provide an electrostatic force between the mirror 614 and the raised electrodes 606, 616 as well as the address electrodes 636 and 637.

The spring tips 607, 617 of the hinge layer 623 are supported by spring tip vias 627 and are physically and electrically coupled to the hinge base 639 of the electrode layer 625. The vias 627, 626, and 629 make mechanical connections and electrically couple the elements on the various metal layers, and when the sacrificial dielectric layers (not shown) that are used in fabrication are removed by etching, these vias become mechanical supports for the hinge layer elements, and mirror via 618 supports the mirror 614 and connects it to the torsional hinge 619. In the arrangements, a single spring tip and a single spring tip via are beneath each tilting corner of the mirror 614, so that when the mirror lands in a landed position, the stiction forces on the mirror are reduced, because the contact area is reduced. The area used for the spring tips is reduced, increasing area for the raised electrodes, and increasing flexibility in positioning the raised electrode vias and the address electrodes.

FIG. 5B illustrates, in a projection view, the pixel 610 of FIG. 5A with the mirror 614 in a landed tilt position. In FIG. 5B, the mirror 614 tilts towards the viewer so that illumination light would be reflected out of the page. The torsional hinge 619 is shown rotating so that a first tilting corner 612 of the mirror 614 is dropping to contact spring tip 617 at a landing tip 620. The opposite tilting corner 613 of mirror 614 tilts upward and away from the corresponding spring tip as the mirror tilts around the mirror tilt axis 651. In an example the mirror tilt is +/−12 degrees with respect to a horizontal or flat position. The spring tip 617 includes a flexible beam 641 with a landing tip 620 and provides a mechanical spring action, which assists in returning the mirror 614 away from the landed position when the electrostatic forces change to either allow the mirror 614 to return to a flat position, or to a cause the mirror 614 to tilt in the opposite direction. In this example arrangement, a single spring tip (617 or 607) with a single landing tip (620 or 630) is positioned beneath each of the opposing tilting corners 612, 613 of mirror 614. The roll axis 653 connecting two tilting corners 612, 613 is perpendicular to the mirror tilt axis 651, the two remaining mirror corners lie along the diagonal of the mirror 614, along mirror tilt axis 651. The positions of the landing tips 620, 630 of the spring tips 607, 617 control the tilt angles of mirror 614 by landing the tilting mirror 614 at the appropriate tilt angle. The raised electrodes 606 and 616 are positioned in the hinge layer (see hinge layer 623 in FIG. 5A) between the torsional hinge 619 and the spring tips 607, 617, and the raised electrodes 606, 616 are symmetric about the roll axis 653. In the illustrated example the raised electrodes 606, 616 include a portion that extends from one side of the roll axis to the other side of the roll axis 653. This symmetric patterning provides balance in the electrostatic forces applied to the bottom surface of the mirror 614, and helps prevent roll of the mirror by reducing the roll moment in the mirror 614 along the roll axis.

In operation, when the pixel 610 is active, electrostatic forces between the raised electrodes 606, 616 and the mirror 614 cause the mirror to tilt in a positive or negative direction, rotating the torsional hinge 619. The mirror via 618 moves with the rotation of the torsional hinge 619, tilting the mirror 614. When the mirror 614 tilts, the bottom surface of the mirror 614 in one of the tilting corners 612 or 613 lands on one of the landing tips 620, 630 of the corresponding spring tip 607, 617 and stops. There is a single spring tip (607 or 617) and a single spring tip via 627 beneath each of the tilting corners 612, 613 of the mirror 614. The mirror 614 in FIG. 5B is in a landed position. The spring tip locations and the distance from the spring tip to the mirror 614 control the mirror tilt angles, which can then be made uniform across a DMD device and between devices formed on a semiconductor wafer. The thickness of the second sacrificial layer (not shown) used in forming mirror 614 and the mirror via 618 control the spacing between the mirror 614 and the spring tips 617.

FIG. 5C illustrates in another projection view of the pixel 610 of the mirror 614 in the landed position. In FIG. 5C the view is looking along the longitudinal axis of the torsional hinge 619. In FIG. 5C, the mirror 614 is tilted to the right so that the tilting corner 613 is now at the left side of the figure and is elevated, tilting upwards and away from the raised electrode 606 and the spring tip 607 that lies beneath tilting corner 613, with landing tip 630 extending away from the torsional hinge 619 and oriented perpendicularly to the longitudinal axis of the torsional hinge 619. A center pad 647 on the torsional hinge 619 is shown carrying the mirror via 618, and as the torsional hinge 619 rotates due to the electrostatic forces between the mirror 614, the raised electrodes 606, 616, and the address electrodes, the mirror 614 tilts. When the mirror tilts, the mirror via 618 also rotates. The tilting corner 612 then lands on the spring tip 617 and landing tip 620 as in FIG. 5B, with the raised electrode 616 beneath tilting corner 612.

FIGS. 6A-6F illustrate, in plan views, the metal layers and vias used to implement the example pixel shown in FIGS. 5A-5C. In FIG. 6A, the electrode layer (see layer 625 in FIG. 5A) is shown with a dashed outline indicating the position of the mirror 614 that is over the electrode layer. The address electrodes 636, 637 are shown beneath the mirror 614, and each address electrode 636, 637 is arranged symmetrically about a roll axis 653 and extending away from the hinge base 639. Hinge base 639 extends along a mirror tilt axis 651 to hinge via support pads at opposite ends on the mirror tilt axis 651, and also extends to spring tip via support pads 640 at either end of the hinge base along the roll axis 653. The hinge base 639 is spaced from the address electrodes 636, 637. In the illustrated arrangement, spring tip via pads 640 are formed as part of hinge base 639 in the electrode layer and extend away from the tilt axis, perpendicular to the tilt axis, and into openings formed in the address electrodes 636, 637. The openings in the address electrodes 636, 637 face the hinge base 639. The spring tip via pads 640 are centered on the roll axis 653 and the layout can be arranged as shown in FIG. 5A so that a metal-to-metal spacing distance (MMsp) is consistent and approximately uniform between hinge base 639 and the address electrodes 636, 637. In an example the spacing MMsp can be a minimum metal to metal spacing for the particular fabrication process. Using uniform metal to metal spacing minimizes the sacrificial spacer topography, improving yields by improving sputter coat processes such as for photoresist coatings. By patterning the address electrodes 636, 637 to be symmetrically spaced on either side of the roll axis 653, the electrostatic force applied to the mirror 614 can be balanced to ensure that when the mirror tilts, the mirror should not have a roll moment, and meets a landing tip of the spring tip along the roll axis without any roll. If, in simulation or in an experiment, a mirror produced using the arrangements does show a roll moment, the shape of the address electrodes 636, 637 can be changed to balance the electrostatic forces. By use of the openings in the address electrodes to allow for the spring tip vias to be positioned extending into the openings, the position of the spring tips can be put farther from the hinge, increasing layout flexibility of the spring tip vias and the address electrodes.

As is described above with respect to FIG. 5A, the address electrodes 636, 637 are each coupled to a memory cell beneath the address electrodes (see memory cell 604 in semiconductor substrate 611 in FIG. 5A) and the address electrodes 636, 637 will carry voltages corresponding to the stored data to the raised electrodes 606, 616. The raised electrodes and the address electrodes apply electrostatic force to the mirror 614 during operation.

FIG. 6B illustrates in another plan view the via pattern for the spring tip vias 627, the hinge vias 629, and the raised electrode vias 626. These vias provide mechanical support for the spring tips, the hinge, and the raised electrodes in the hinge layer (see torsional hinge 619, raised electrodes 606, 616, spring tips 607, 617 in hinge layer 623 in FIG. 5A). In FIG. 6B, a dashed line indicates the position of the mirror 614 that is over the spring tip vias 627, the hinge vias 629, and the raised electrode vias 626. In FIG. 6B, hinge vias 629 are positioned at either end of the hinge (see torsional hinge 619 in FIG. 5A) and couple the ends of the torsional hinge 619 (see FIG. 5A) to the hinge base 639 (see FIG. 6A) along the tilt axis 651. Spring tip vias 627 are positioned beneath the opposing tilting corners of the mirror 614 and couple the spring tips (see 607, 617 in FIG. 5A) to hinge base 639 (see FIG. 6A). The spring tip vias 627 are aligned with the roll axis 653 and in the example arrangement for pixel 610 are equidistant from the tilt axis 651. Raised electrode vias 626 are also beneath the tilting corners of mirror 614.

FIG. 6C illustrates, in a plan view, the hinge layer (see layer 623 in FIG. 5A) for an example arrangement. In FIG. 6C, a dashed line indicates the position of the mirror 614 that is over the hinge layer 623. In forming the DMD pixels, the electrode layer (see 625 in FIG. 5A) is deposited and patterned over a semiconductor substrate that includes the memory cells (see semiconductor substrate 611 and memory cell 604 in FIG. 5A). In FIG. 6C, the hinge layer is illustrated including the spring tips 607, 617, the raised electrodes 606, 616, and the hinge 619.

In FIG. 6C, the raised electrodes 606, 616 are symmetrically shaped to have equal area on either side of the roll axis 653, and the raised electrodes have a portion that extend across the roll axis 653, which allows for balancing of the electrostatic forces on the mirror to ensure the mirror tilts along the tilt axis without creating any roll moment along the roll axis. Raised electrode shapes different from the examples shown in the figures can be used to compensate for any roll moment that is observed in an experiment or in a simulation.

FIG. 6D illustrates, in a combined plan view, the metal layers and vias of the pixel. The address electrodes 636, 637 and hinge base of the electrode layer 625 are shown with the raised electrodes 606, 616 shown between the spring tips 607, 617 and the torsional hinge 619. The torsional hinge 619 has a mirror via 618 formed at a central via pad on the torsional hinge 619. The mirror 614 is shown with a dashed line to indicate where the elements are beneath the mirror 614. The landing tip 620 extends from the spring tip 617 and is spaced from the hinge by a distance Dh,st, which can be for example 2.2 microns for an example mirror with a 6.4 micron diagonal pitch, and the raised electrode 616 is spaced from the hinge by a distance Dh,e which is less than the spring tip landing tip distance. The distance Dh,st from the hinge to the landing tip 620 is proportionally greater than in other conventional DMD pixels, which improves the flexibility in layout for the elements. Use of a single spring tip and single spring tip via for each tilting corner results in additional area for other elements.

FIG. 6E illustrates the mirror 614 of FIG. 6D in a cross sectional view. The cross section of FIG. 6E is taken along the line 6E-6E in FIG. 6D, which is along the tilt axis. The mirror 614 is mechanically supported and electrically connected to torsional hinge 619 by the mirror via 618. The torsional hinge 619 is a planar shape mechanically supported and electrically connected to the hinge base 639 by the hinge vias 629. An anti-reflective coating (sometimes referred to as an “ARC”) 642 is shown overlying the hinge base 639, which can increase performance by reducing unwanted reflections from the elements below mirror 614.

FIG. 6F illustrates, in another cross sectional view, the pixel of FIG. 6D. The cross section of FIG. 6F is taken along the line 6F-6F in FIG. 6D, which is along the roll axis. The mirror 614 is mechanically supported and electrically connected to torsional hinge 619 by the mirror via 618. Spring tips 607, 617 are supported and electrically connected to the hinge base 639 by spring tip vias 627. Raised electrodes 606, 616 are shown spaced from the torsional hinge 619 and the spring tips 607, 617, positioned between the spring tips 607, 617 and the torsional hinge 619. ARC 642 is shown overlying the hinge base 639 and the address electrodes 637, 636, which can increase performance by reducing unwanted reflections. The address electrodes 636, 637 are also shown beneath the mirror 614.

FIG. 6G illustrates, in a projection view, the pixel 610 with the mirror 614 shown transparently to illustrate the positions of the elements. The mirror 614 is mounted to torsional hinge 619 by mirror via 618. In the arrangements, the torsional hinge 619 is supported by and connected to hinge vias 629 at each end of the hinge, and the hinge 619 has a longitudinal axis that extends diagonally with respect to the mirror 614, so that the mirror 614 can tilt along tilt axis 651. The first and second tilting corners 612, 613 of the mirror 614 each have a corresponding spring tip 607, 617 under the mirror. The spring tips 607 and 617 include a landing tip 630, 620, respectively, that extend along the roll axis 653. Raised electrodes 606, 616 are under the tilting corners 612, 613 and in the same metal layer as the spring tips 607, 617 and the torsional hinge 619. In the arrangements, the raised electrodes 606, 616 are shaped symmetrically about the roll axis 653 and a portion extends across the roll axis 653. The spring tips 607, 617 are spaced from the torsional hinge 619 and the raised electrodes 606 and 616 lie between the torsional hinge 619 and the spring tips 607, 617. The raised electrodes 606, 616 are supported by raised electrode vias 626 which electrically couple the raised electrodes 606, 616 to the address electrodes formed below the raised electrodes 606, 616. The address electrode (see 636, 637 in FIG. 6D) for each tilting corner of the mirror 614 extends into the area beneath the mirror corner and has an opening facing the torsional hinge 619, the spring tip vias 627 are positioned within these openings. The spring tips 607, 617 are then positioned so that the electrostatic force from the address electrodes and the raised electrode 606, 616 is surrounding the spring tips 607, 617, and the areas of the metal layers that form address electrodes 636, 637 and raised electrodes 606, 616 are formed symmetrically on either side of the roll axis 653, to balance the electrostatic forces. When the mirror 614 is not subject to the electrostatic forces from the address electrodes and the raised electrodes, the torsional hinge 619 will return to a flat position as shown in FIG. 6G and the mirror 614 will lie in a horizontal plane (as the elements are oriented in FIG. 6G).

In the arrangements a single spring tip via is formed, instead of multiple spring tip vias used in conventional arrangements, for the tilting corners of the mirror. By using a single spring tip via for each tilting corner, the area available for the raised electrode vias is increased, and device scaling is enhanced, as the minimum spacing rules from via to via can be more easily met (because the arrangements use fewer vias in the mirror area). In the arrangements, the pixels are formed with spring tips with a landing tip that forms a small contact area for each landed position. In the example arrangement shown in FIGS. 5A-5C, a single spring tip landing tip will be contacted by the bottom surface of the mirror 614 in each landed state. The stiction forces in the arrangements are therefore reduced, for example by as much as 50%, by use of the single spring tip landing tip that contacts the mirror when the mirror is landed, which enables the use of smaller pixel dimensions with reduced stiction. Use of the arrangements reduces the likelihood of stuck pixels, particularly when the pixels are scaled to smaller dimensions. Further advantages attained by use of the arrangements include additional area for electrode support vias (due to the use of a single spring tip via beneath the tilting corners of the mirror), and that additional area provides additional flexibility in layout that can further enhance pixel scaling.

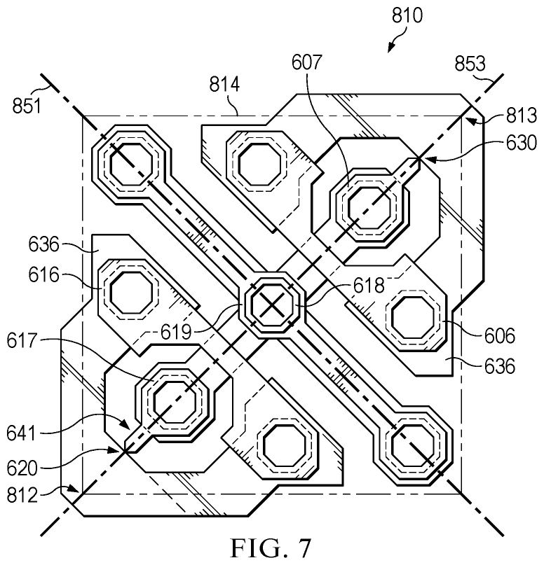

FIG. 7 illustrates, in a plan view, an example orientation of the pixel of the arrangement oriented for use in an orthogonal DMD array. In FIG. 7, pixel 810 includes a mirror 814 with a diagonal tilt axis 851 and a first tilting corner 812 and a second tilting corner 813, with a roll axis 853. The mirror 814 will tilt so that the first tilting corner 812, in the lower left hand corner of FIG. 7, can tilt towards a spring tip beneath it or away from the spring tip, similarly the second tilting corner 813 can tilt towards a spring tip beneath it or away from the spring tip. This orientation of the pixel can be used to form the orthogonal mirror array of FIG. 4, for example. In an alternative arrangement, the pixel 810 can be rotated to be positioned with the tilt axis 851 extending from the lower left of the figure to the upper right, and used in the orthogonal mirror array such as in FIG. 4. Pixel 810 includes the elements of pixel 610 in FIG. 5A, and is oriented so that in an orthogonal array, the pixels have the parallel sides such as shown in FIG. 4, instead of the diamond pixel orientation of FIG. 3A.

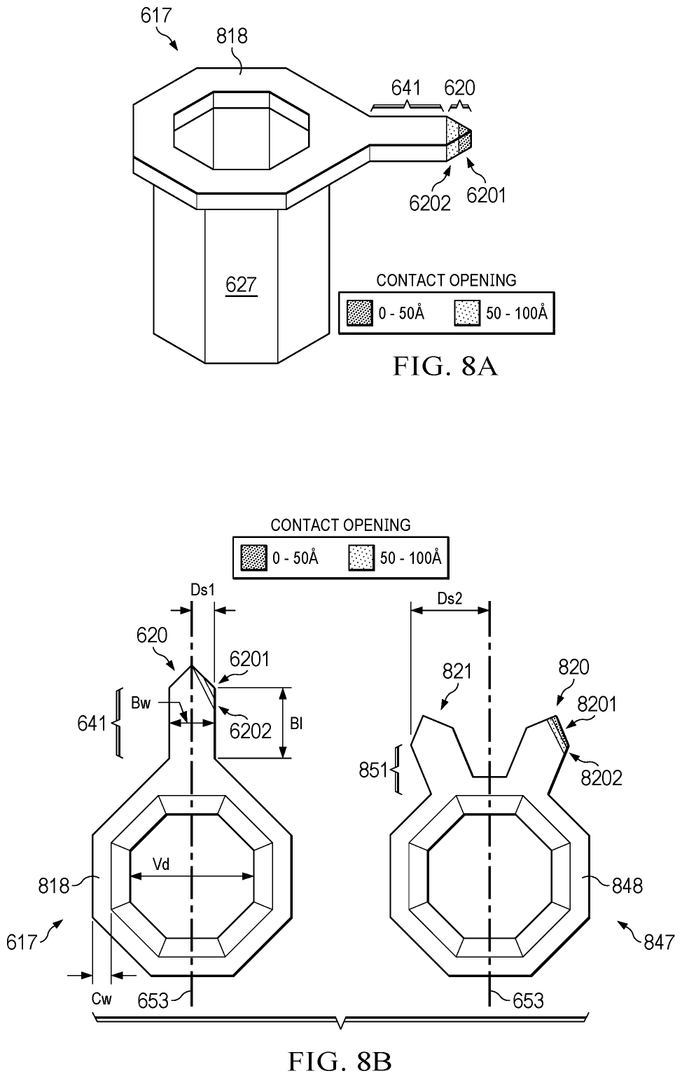

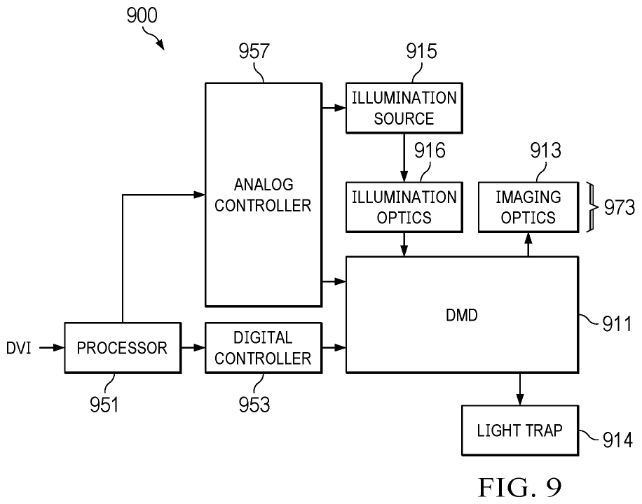

FIG. 8A illustrates, in a close up projection view, additional details of a spring tip 617 for use with the arrangements. The spring tip 617 has a spring tip beam 941 extending from a spring tip collar 818 connected to spring tip via 627 and ending in a landing tip 620. As shown by the shading patterns and the key in FIG. 9A, the portion of the landing tip 620 that contacts the mirror when the mirror is landed can vary, contact area 6201 extends from a contact length of 0 Angstroms to 50 Angstroms, and contact area 6202 extends from a contact length of 50 Angstroms to 100 Angstroms. In the example of FIG. 8A, the flexible beam 641 has a single width along its length extending from spring tip collar 818. The spring tip 617 is formed with the torsional hinge and can be of the same material, an aluminum or aluminum alloy can be used, such as Al₃Ti. The spring tip beam 641 is flexible but has enough stiffness to provide a defined landing position for the mirror when the mirror tilts to a landed position. In alternative arrangements, the width of the spring tip beam 641 can be made wider in portions or shaped differently to increase stiffness using in plane features.

FIG. 8B illustrates, in a top view, the spring tip 617 of FIG. 8A (and see FIGS. 5A-5C) and in an alternative arrangement a spring tip 847 with split landing tips 820, with one landing tip 820 on either side of the roll axis 653. In FIG. 8B, the spring tip 617 has the flexible spring tip beam 841 extending from the spring tip collar 818 to a single landing tip 620. In additional alternatives, the flexible spring tip beam 641 can have portions that are wider near the spring tip collar 818, and by using these different shapes, various stiffness can be achieved without changing the thickness. Example dimensions for the spring tip via diameter Vd include via diameters from 0.4-0.7 microns. Example dimensions for the flexible beam length B1 include beam lengths from 0.3-0.7 microns. Example dimension of the collar width Cw include from 0.05-0.2 microns. The spring tip beam 641 can have a range of beam widths Bw from 0.15 to 0.6 microns. The example spring tip beam 641 has tip 620 with two sides at a 45 degree angle to form a triangle tip, other tip shapes and other angles can be used. Ideally the tilting mirror corner will contact the spring tip landing tip at a single point along the roll axis, but the mirror corner may have a roll moment, with contact areas 6201, 6202 varying in size depending on the roll moment. In FIG. 8B, the landing tip 620 is shown with a spacing Ds1 to the side of the landing tip. In an example with a mirror with more roll moment, a split landing tip can be used to add stability by providing a landing tip that is spaced farther from the roll axis.

The spring tip 847 has a pair of landing tips 821, 820 on spring tip beams 851 with the landing tips 820, 821 symmetrically arranged on either side of the roll axis 653. In an example where mirror roll is observed, the alternative spring tip 847 can provide further stability. The distance Ds1 from the roll axis to the contact area 6201 and 6202 for the single spring tip 617 is much less than the distance Ds2 from the roll axis to the side of the landing tip 820, with contact areas 8201 for 0-50 Angstroms, and contact area 8202 for 50-100 Angstroms. The split landing tips 820, 821 can be of various shapes and the stiffness or flexibility can be varied by use of various widths along the length of beam 851, and the angle of the tips 820, 821 can be varied from the examples shown. In an example, the split landing tips 820, 821 can be spaced from the roll axis by a distance Ds2 of between 0.2 and 0.6 microns. In the arrangements the tilted mirror lands on a single landing tip, which reduces stiction when compared to conventional mirror designs which use two landing tips for each tilted mirror corner. Both spring tip 617 and spring tip 847 show examples for a single spring tip to be positioned beneath each tilting corner for a mirror in a DMD pixel. Use of a single spring tip beneath each tilting corner improves stiction (compared to DMD pixels formed without the use of the arrangements), increases available area beneath the mirror, and improves device scaling due to the flexibility in the layout that accrues by use of the arrangements. The single spring tip in the hinge layer for each tilting corner of the mirror has a corresponding single spring tip via, increasing the area available for raised electrode vias and increasing via layout flexibility over prior approaches.

FIG. 9 illustrates, in a block diagram, various elements of a system 900 for use with arrangements. A DMD 911 which includes the pixels of the arrangements with a single spring tip for each tilting corner of the mirrors is used. Processor 951, which can be implemented using a digital signal processor (DSP), a microprocessor, or a microcontroller unit (MCU), receives digital video input (DVI) signals. A digital controller 953 provides digital data to the DMD 911, including data for display. Analog controller 957 controls power signals to the DMD 911, and to the illumination source 915. Light from the illumination source 915 is optically coupled to the DMD 911 by illumination optics 916. On state patterned light from the on state pixels of DMD 911 is then optically coupled to imaging optics 913. The on state patterned light is then projected as on state light 973 and output from the system 900. Off state patterned light reflected from pixels in DMD 911 that are in the off state is optically coupled to a light trap 914.

Although the example illustrative arrangements have been described in detail, it should be understood that various changes, substitutions and alterations can be made herein without departing from the spirit and scope of the present application as defined by the appended claims. Accordingly, the appended claims are intended to include within their scope processes, machines, manufacture, compositions of matter, means, methods, or steps that provide equivalents to the examples disclosed.

What is claimed is:

1. An apparatus, comprising:
an electrode layer comprising address electrodes and a hinge base;
a hinge layer over the electrode layer, the hinge layer comprising:
a torsional hinge having a longitudinal axis between opposite ends;
a first single spring tip and a second single spring tip spaced from the torsional hinge; and
raised electrodes spaced from the torsional hinge, from the first single spring tip, and from the second single spring tip; and
a mirror over the hinge layer, the mirror having a tilt axis on diagonal between a first corner and a second corner, the tilt axis aligned with the longitudinal axis of the torsional hinge, the mirror having a first tilting corner and a second tilting corner opposing one another across the tilt axis, the first single spring tip under the first tilting corner and the second single spring tip under the second tilting corner.

2. The apparatus of claim 1, further comprising:
a first spring tip via supporting the first single spring tip and a second spring tip via supporting the second single spring tip, the first spring tip via and the second spring tip via mechanically and electrically coupling the first single spring tip and the second single spring tip, respectively, to the hinge base.

3. The apparatus of claim 2, further comprising raised electrode vias supporting the raised electrodes and electrically coupling the raised electrodes to the address electrodes.

4. The apparatus of claim 3, further comprising a mirror via on the torsional hinge supporting the mirror and electrically coupling the mirror to the torsional hinge.

5. The apparatus of claim 4, further comprising:
hinge vias at the opposite ends of the torsional hinge, the hinge vias supporting the torsional hinge and electrically coupling the torsional hinge to the hinge base.

6. The apparatus of claim 5, wherein the mirror is configured to tilt about the tilt axis to a first angle from a horizontal position and the first tilting corner is configured to contact the first single spring tip, and the mirror is configured to tilt about the tilt axis to a second angle opposite the first angle and the second tilting corner is configured to contact the second single spring tip.

7. The apparatus of claim 6, wherein the first spring tip via for the first single spring tip is a single spring tip via beneath the first tilting corner of the mirror, and the second spring tip via for the second single spring tip is a single spring tip via beneath the second tilting corner of the mirror.

8. The apparatus of claim 2, the mirror having a roll axis perpendicular to the tilt axis and intersecting the tilt axis at a center of the mirror, the first tilting corner and the second tilting corner aligned with the roll axis; and
the first single spring tip further comprising:
a spring tip beam flexibly extending from a spring tip collar, the spring tip collar contacting the first spring tip via, the spring tip beam extending along the roll axis toward the first tilting corner of the mirror; and
at least one landing tip at an end of the spring tip beam.

9. The apparatus of claim 8, wherein the spring tip beam of the first single spring tip has the at least one landing tip aligned with the roll axis.

10. The apparatus of claim 8, wherein the spring tip beam of the first single spring tip has the at least one landing tip that is offset from the roll axis.

11. The apparatus of claim 8, wherein the at least one landing tip further comprises a first landing tip and further comprising a second landing tip spaced from the first landing tip, the first landing tip and the second landing tip on opposite sides of the roll axis.

12. An apparatus, comprising:
an electrode layer comprising address electrodes;
a mirror layer comprising a mirror configured to tilt about a tilt axis that runs diagonally between a first corner and a second corner, the mirror having a first tilting corner and a second tilting corner; and
a hinge layer over the address electrodes and beneath the mirror layer, the hinge layer comprising:
a torsional hinge having a longitudinal axis between two ends;
raised electrodes spaced from the torsional hinge; and
a first spring tip beneath the first tilting corner and a second spring tip beneath the second tilting corner, the first tilting corner configured to contact the first spring tip when the mirror tilts at a first angle with respect to a horizontal position, and the second tilting corner configured to contact the second spring tip when the mirror tilts at a second angle with respect to the horizontal position.

13. The apparatus of claim 12, and further comprising a first spring tip via supporting the first spring tip and a second spring tip via supporting the second spring tip, the first spring tip and the first spring tip via are beneath the first tilting corner of the mirror and are a single spring tip and a single spring tip via for the first tilting corner of the mirror.

14. The apparatus of claim 12, wherein one of the raised electrodes in the hinge layer is between the first spring tip and the torsional hinge, and spaced from the first spring tip.

15. The apparatus of claim 14, wherein the mirror has a roll axis perpendicular to the tilt axis and intersecting the tilt axis at a center of the mirror, the first tilting corner and the second tilting corner aligned with the roll axis, and the one of the raised electrodes is symmetrical about the roll axis and has a portion extending across the roll axis.

16. The apparatus of claim 12, wherein the address electrodes are beneath the first tilting corner and the second tilting corner of the mirror, and the address electrodes further have openings facing a center of the mirror, and the first spring tip via and the second spring tip via are mounted on spring tip via pads of a hinge base in the electrode layer that extend into the openings in the address electrodes.

17. An apparatus comprising:
a semiconductor substrate;
an electrode layer over the semiconductor substrate, the electrode layer comprising a first address electrode, a second address electrode spaced apart from the first address electrode, and a hinge base spaced from the first address electrode and the second address electrode;
a hinge layer over the electrode layer, the hinge layer comprising:
a torsional hinge having a longitudinal axis between opposite ends;
a first single spring tip and a second single spring tip spaced from the torsional hinge; and
raised electrodes spaced from the torsional hinge, from the first single spring tip, and from the second single spring tip;
a mirror over the hinge layer, the mirror having a tilt axis on a diagonal between a first corner and a second corner, the tilt axis aligned with the longitudinal axis of the torsional hinge;
a first spring tip via supporting the first single spring tip and a second spring tip via supporting the second single spring tip, the first spring tip via and the second spring tip via mechanically and electrically coupling the first spring tip and the second spring tip, respectively, to the hinge base; and
the first single spring tip under the first tilting corner and the second single spring tip under the second tilting corner.

18. The apparatus of claim 17, the mirror having a roll axis perpendicular to the tilt axis and intersecting the tilt axis at a center of the mirror, the first corner and the second corner aligned with the roll axis, the first single spring tip further comprising:
a spring tip beam flexibly extending from the first spring tip via along the roll axis toward the first corner of the mirror; and
at least one landing tip at an end of the spring tip beam.

19. The apparatus of claim 18, wherein the spring tip beam of the first single spring tip has the at least one landing tip aligned with the roll axis.

20. The apparatus of claim 18, wherein the at least one landing tip further comprises a first landing tip and a second landing tip spaced from the first landing tip, the first landing tip and the second landing tip on opposite sides of the roll axis.
